(19) United States
(12) Patent Application Publication
(10) Pub. No.: US 2025/0063111 A1
(43) Pub. Date: Feb. 20, 2025

(54) ELECTRONIC DEVICE

(71) Applicant: Samsung Display Co., Ltd., Yongin-si (KR)

(72) Inventors: KWANGRAE LEE, Yongin-si (KR); DO-HYEON KIM, Yongin-si (KR); YUN HEO, Yongin-si (KR)

(21) Appl. No.: 18/759,666

(22) Filed: Jun. 28, 2024

(30) Foreign Application Priority Data
Aug. 17, 2023 (KR) 10-2023-0107438

(51) Int. Cl. H04M 1/02

(52) U.S. Cl. CPC H04M 1/0268; H04M 1/0216; H04M 2250/22

(57) ABSTRACT

Disclosed is an electronic device including a display module including a bending area bent along a virtual bending axis, a first non-bending area and a second non-bending area spaced apart from each other with the bending area therebetween, a front surface, and a rear surface opposite to the front surface, a first protective member below the rear surface and overlapping the first non-bending area, a second protective member above the rear surface, overlapping the second non-bending area, and facing the first protective member, a functional layer between the first protective member and the second protective member, and a protective layer on the rear surface, overlapping the bending area, and contacting side surfaces of the first protective member, the functional layer, and the second protective member.

### CROSS-REFERENCE TO RELATED APPLICATIONS

The present application claims priority to, and the benefit of, Korean Patent Application No. 10-2023-0107438, filed on Aug. 17, 2023, in the Korean Intellectual Property Office, the entire disclosure of which is incorporated herein by reference.

### BACKGROUND

### 1. Field

Embodiments of the present disclosure described herein relate to an electronic device having improved reliability.

### 2. Description of the Related Art

Electronic devices are activated according to electrical signals. Electronic devices may include devices including various electronic components, such as a display unit that displays an image or an input-sensing unit that detects an external input. Electronic components may be electrically connected to each other through variously arranged signal lines.

Various numbers of signal lines may be provided according to the number of electronic components or a processing environment, and the signal lines are designed to be bent and arranged in an appropriate space to reduce or prevent electrical signal interference within a panel area.

### SUMMARY

Embodiments of the present disclosure provide an electronic device in which, as an area to which a resin located in a space between bent panels is applied is limited, penetration of the resin between adhesive layers may be reduced or prevented.

According to one or more embodiments, an electronic device includes a display module including a bending area bent along a virtual bending axis, a first non-bending area and a second non-bending area spaced apart from each other with the bending area therebetween, a front surface, and a rear surface opposite to the front surface, a first protective member below the rear surface and overlapping the first non-bending area, a second protective member above the rear surface, overlapping the second non-bending area, and facing the first protective member, a functional layer between the first protective member and the second protective member, and a protective layer on the rear surface, overlapping the bending area, and contacting side surfaces of the first protective member, the functional layer, and the second protective member.

The side surface of the first protective member may be closer to the bending area than the side surfaces of the functional layer and the second protective member.

The side surface of the functional layer may expose a portion of a rear surface of the first protective member that contacts the protective layer.

The electronic device may further include a first adhesive layer between the first non-bending area and the first protective member, a second adhesive layer between the first protective member and the functional layer, a third adhesive layer between the functional layer and the second protective member, and a fourth adhesive layer between the second non-bending area and the second protective member.

The first to fourth adhesive layers may include a pressure sensitive adhesive (PSA) film, an optically clear adhesive (OCA) film, or an optically clear resin (OCR).

The protective layer may contact side surfaces of the first to fourth adhesive layers.

The electronic device may further include a window panel including a base part above the display module, a bezel pattern at at least a portion of an edge of a rear surface of the base part, and a hard coating layer above a front surface of the base part.

The rear surface of the base part or the front surface of the base part overlapping the bezel pattern may have a chamfered shape.

The electronic device may further include a driving element on the front surface overlapping the second non-bending area.

The electronic device may further include a main circuit board on the front surface and overlapping the second non-bending area.

The electronic device may further include a cover member above the front surface and overlapping the bending area.

The electronic device may further include a reflection-preventing panel above the display module, and having a side surface contacting the cover member.

The display module may include a display panel including a base layer, a transistor above the base layer, a light-emitting element connected to the transistor, and an encapsulation layer configured to cover the light-emitting element and including inorganic layers and an organic layer, and an input sensor directly on the encapsulation layer and including conductive layers and at least one sensing insulating layer.

The protective layer may include a resin.

According to one or more embodiments, a method of manufacturing an electronic device includes providing a preliminary electronic device including a display module including a first non-bending area, a bending area, and a second non-bending area, a first protective member on a rear surface of the display module and overlapping the first non-bending area, a second protective member on the rear surface of the display module and overlapping the second non-bending area, and a functional layer on the first protective member, applying a resin to a first area overlapping the bending area and between the first protective member and the second protective member, and to a second area at an edge of the functional layer adjacent to the bending area and spaced apart from the first area, and bending the bending area with respect to a bending axis extending in one direction such that the second protective member faces the functional layer.

An area of the first area may be larger than an area of the second area.

The second area may extend in the one direction.

The second area may include sub-units spaced apart from each other in the one direction.

The method may further include combining the resin applied to the first area and the resin applied to the second area in a space defined between the first protective member, the functional layer, the second protective member, and the rear surface of the display module overlapping the bending area.

The method may further include inserting an additional resin into the space after the bending of the bending area.

### BRIEF DESCRIPTION OF THE DRAWINGS

The above and other aspects of the present disclosure will become apparent by describing in detail embodiments thereof with reference to the accompanying drawings.

FIG. 1 is a perspective view of an electronic device according to one or more embodiments of the present disclosure.

FIG. 2A is an exploded perspective view of the electronic device according to one or more embodiments of the present disclosure.

FIG. 2B is a block diagram of the electronic device according to one or more embodiments of the present disclosure.

FIG. 3A is a cross-sectional view of a display module according to one or more embodiments of the present disclosure.

FIG. 3B is an enlarged cross-sectional view of the display module of FIG. 3A.

FIG. 4 is a plan view of a display panel according to one or more embodiments of the present disclosure.

FIG. 5 is a plan view of an input sensor according to one or more embodiments of the present disclosure.

FIG. 6A is a cross-sectional view of the electronic device according to one or more embodiments of the present disclosure.

FIG. 6B is a cross-sectional view of the electronic device according to one or more embodiments of the present disclosure.

FIGS. 7A to 7D are cross-sectional views illustrating a method of manufacturing the electronic device according to one or more embodiments of the present disclosure.

FIG. 8 is a rear view of the display panel according to one or more embodiments of the present disclosure.

FIG. 9 is a rear view of the display panel according to one or more embodiments of the present disclosure.

FIG. 10 is a rear view of the display panel according to one or more embodiments of the present disclosure.

FIG. 11A is a cross-sectional view illustrating an electronic device according to a comparative example.

FIG. 11B is a rear view of a display panel according to a comparative example.

FIG. 11C is a cross-sectional view illustrating the electronic device according to a comparative example.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or 1 below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

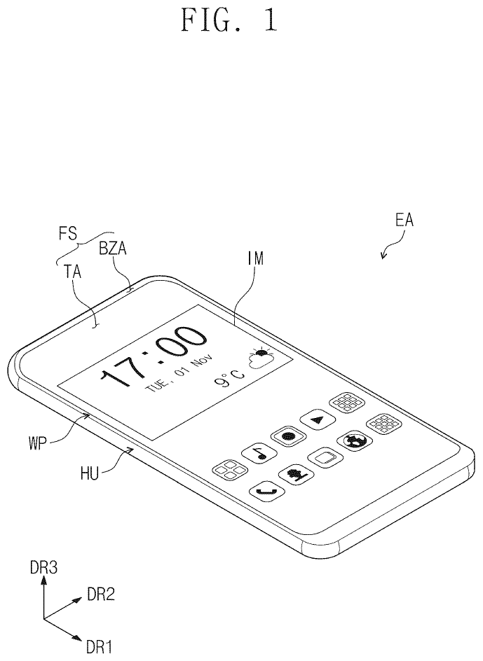

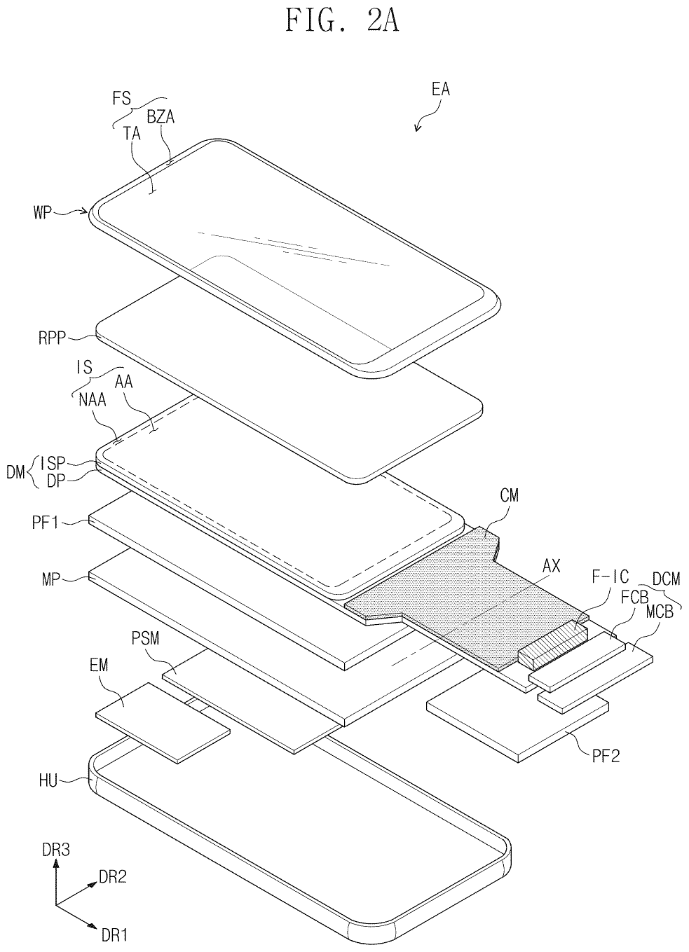

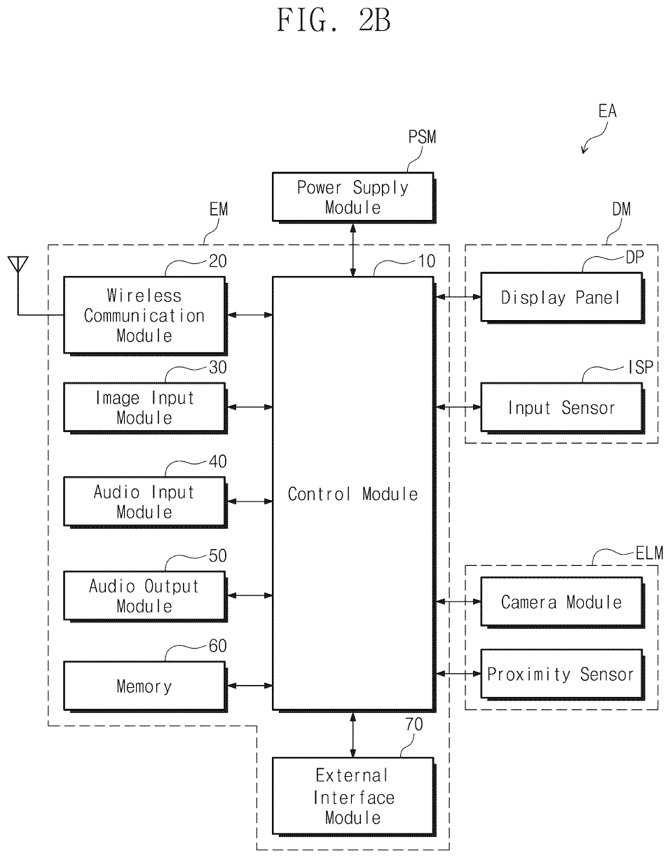

FIG. 1 is a perspective view of an electronic device according to one or more embodiments of the present disclosure. FIG. 2A is an exploded perspective view of the electronic device according to one or more embodiments of the present disclosure. FIG. 2B is a block diagram of the electronic device according to one or more embodiments of the present disclosure.

Referring to FIGS. 1 to 2B, an electronic device EA may be a device that is activated according to an electric signal. The electronic device EA may include one or more embodiments. For example, the electronic device may be used in large electronic devices, such as televisions, monitors, or outdoor billboards, as well as small and medium-sized electronic devices, such as personal computers (PCs), laptop computers, personal digital assistants, vehicle navigation units, game consoles, portable electronic devices, and cameras. Further, these are merely presented as one or more embodiments, and may be employed to other electronic devices without deviating from the present disclosure. In one or more embodiments, the electronic device EA is illustrated as a smart phone.

The electronic device EA may display an image IM in a third direction DR3 on a display surface FS that is parallel to a first direction DR1 and a second direction DR2. The image IM may include a still image as well as a dynamic image. In FIG. 1, a watch window and icons are illustrated as an example of the image IM. The display surface FS on which the image IM is displayed may correspond to a front surface of the electronic device EA, and may correspond to a front surface of a window panel WP.

In one or more embodiments, a front surface (or an upper surface) and a rear surface (or a lower surface) of each component are defined with respect to a direction in which the image IM is displayed. The front surface and the rear surface may face each other in the third direction DR3, and a normal direction of each of the front and rear surfaces may be parallel to the third direction DR3.

Meanwhile, directions indicated by the first to third directions DR1, DR2, and DR3 are relative concepts, and may be changed to other directions. In the present specification, the wording “on a plane” may mean a state when viewed in the third direction DR3.

Referring to FIG. 2A, the electronic device EA may include the window panel WP, a reflection-preventing panel RPP, a display module DM, a cover member CM, a driving element F-IC, a driving controller DCM, protective members PF1 and PF2, a functional layer MP, an electronic module EM, a power supply module PSM, and a housing HU. In one or more embodiments, the window panel WP and the housing HU may be coupled to each other to constitute an exterior of the electronic device EA. FIG. 2A illustrates a state before one area of the display module DM is bent.

The window panel WP may include an optically transparent insulating material. For example, the window panel WP may include glass or plastic. The window panel WP may have a multi-layer structure or a single-layer structure. For example, the window panel WP may include a plurality of plastic films coupled through an adhesive, or may include a glass substrate and a plastic film coupled through an adhesive.

As described above, the display surface FS of the window panel WP may define the front surface of the electronic device EA. A transmissive area TA may be an optically transparent area. For example, the transmissive area TA may be an area having a visible light transmittance of about 90% or more.

A bezel area BZA may be an area having a relatively low light transmittance as compared to the transmissive area TA. The bezel area BZA may define a shape of the transmissive area TA. The bezel area BZA may be adjacent to the transmissive area TA, and may surround the transmissive area TA.

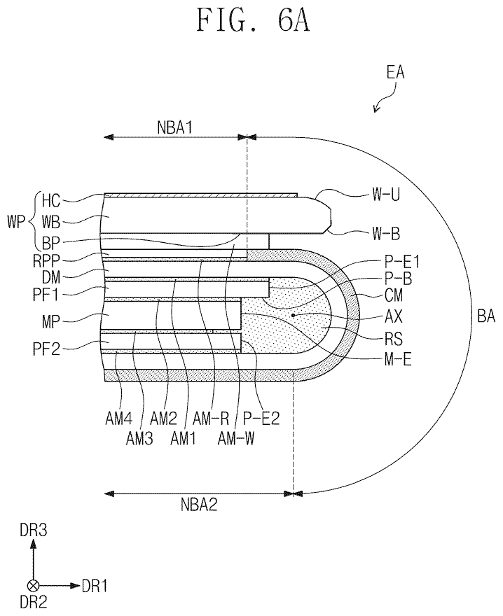

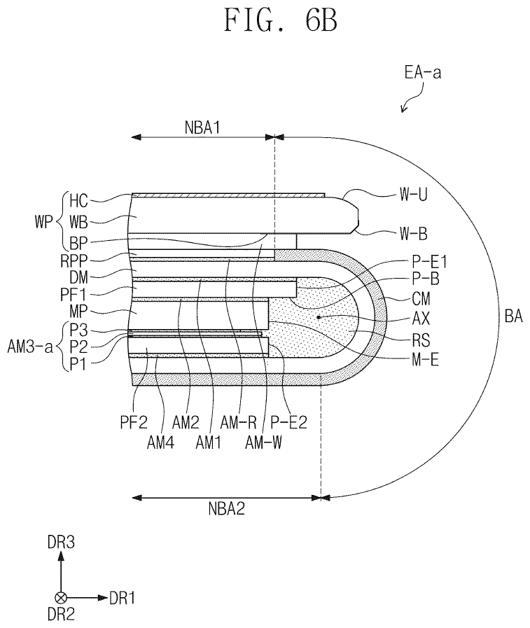

The bezel area BZA may be defined by a bezel pattern BP (see FIG. 6A), which will be described below, and may have a color corresponding to a color of the bezel pattern BP (see FIG. 6A). The bezel area BZA may overlap a peripheral area NAA of the display module DM to reduce or prevent visual recognition of the peripheral area NAA from the outside. Meanwhile, this is illustrated only an example, and in the window panel WP, the bezel area BZA may be omitted according to one or more embodiments of the present disclosure.

The reflection-preventing panel RPP may be located under the window panel WP. The reflection-preventing panel RPP may reduce reflectance of an external light beam input from the window panel WP. The reflection-preventing panel RPP according to one or more embodiments of the present disclosure may be omitted, and may be a component included inside the display module DM.

The display module DM may display the image IM, and may detect an external input. The display module DM may include a front surface IS including an active area AA and the peripheral area NAA. The active area AA may be an area that is activated according to an electric signal.

In one or more embodiments, the active area AA may be an area on which the image IM is displayed, and at the same time, may be an area in which the external input is detected. The transmissive area TA may overlap the entire surface or at least a portion of the active area AA.

Accordingly, a user may visually recognize the image IM, or may provide the external input, through the transmissive area TA. However, this is illustrated only an example. In the display module DM according to one or more embodiments of the present disclosure, an area on which the image IM is displayed and an area in which the external input is detected may be separated from each other within the active area AA, and the present disclosure is not limited to one or more embodiments.

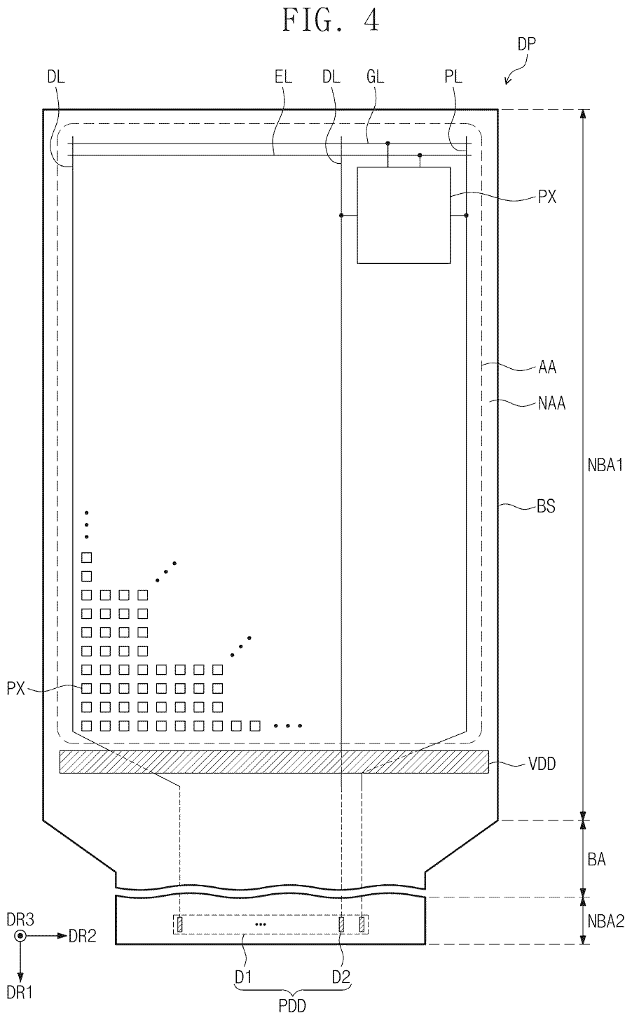

The peripheral area NAA may be an area covered by the bezel area BZA. The peripheral area NAA may be adjacent to the active area AA. The peripheral area NAA may surround the active area AA. A driving element, a driving wiring line, and the like for driving pixels PX (see FIG. 4) arranged in the active area AA may be arranged in the peripheral area NAA.

The display module DM may include a display panel DP and an input sensor ISP. The display panel DP may be a component that substantially generates the image IM. The image IM generated by the display panel DP may be visually recognized by the user from the outside through the transmissive area TA. The input sensor ISP may detect the external input that is input through the window panel WP.

The display module DM according to the present disclosure may include a first non-bending area NBA1 (see FIG. 4), a bending area BA (see FIG. 4), and a second non-bending area NBA2 (see FIG. 4) that are sequentially arranged in the first direction DR1 in a state in which the display panel DP is not bent. The bending area BA may be bent along a virtual bending axis AX (see FIG. 6A) extending in the second direction DR2. In a state in which the bending area BA is bent, a rear surface of the display module DM overlapping the first non-bending area NBA1 and a rear surface of the display module DM overlapping the second non-bending area NBA2 may face each other.

The external input may include various types of inputs provided from the outside of the electronic device EA. For example, the external input may include a contact by a part of a body of the user, such as a hand, as well as an external input (for example, hovering) applied in proximity to the electronic device EA or adjacent to the electronic device EA at a distance (e.g., predetermined distance). Further, the external input may have various forms, such as force, pressure, and light, and the present disclosure is not limited to one or more embodiments.

The cover member CM is located on the display module DM. For example, the cover member CM may be located on the display panel DP overlapping the bending area BA. The cover member CM may alleviate stresses generated when a portion of the display panel DP, which overlaps the bending area BA, is bent.

The cover member CM according to one or more embodiments includes a synthetic resin. For example, the cover member CM may include at least one of acrylonitrile butadiene styrene copolymer (ABS), urethane acrylate (UA) polyurethane (PU), polyethylene (PE), ethylene vinyl acetate (EVA), or polyvinyl chloride (PVC).

The driving element F-IC may include driving elements for driving the display panel DP. For example, the driving element F-IC may include a signal controller that controls the display panel DP. The signal controller may receive input image signals, and may convert the input image signals into image data corresponding to operations of the pixels PX. Further, the signal controller may receive various control signals, for example, a vertical synchronization signal, a horizontal synchronization signal, a main clock signal, and a data enable signal, and may output signals corresponding to the signals. Further, the driving element F-IC may further include a circuit unit that controls the input sensor ISP, and the present disclosure is not limited to one or more embodiments.

The driving controller DCM may include a main circuit board MCB and a flexible circuit board FCB. The driving controller DCM may be electrically connected to the display module DM, and may control the display panel DP and the input sensor ISP. The flexible circuit board FCB may be connected to a distal end of the display panel DP, and may connect the main circuit board MCB and the driving element F-IC.

The main circuit board MCB may further include a plurality of electronic components mounted on the main circuit board MCB. The electronic components may be electrically connected through circuit wiring lines. The main circuit board MCB may be electrically connected to the display module DM connected to the driving element F-IC through the flexible circuit board FCB.

Further, the main circuit board MCB may further include a protective cap that covers the electronic components. The protective cap may be a protective cover made of a metal, and may be coupled to the main circuit board MCB through soldering. The main circuit board MCB may be electrically connected to a motherboard of the electronic module EM through a connector. The flexible circuit board FCB may include a flexible film, a plurality of circuit wiring lines arranged on the flexible film, and pads corresponding to pads included in the display panel DP.

The protective members PF1 and PF2 may be arranged on a rear surface of the display panel DP. The first protective member PF1 may be located on the rear surface of the display module DM overlapping the first non-bending area NBA1, and the second protective member PF2 may be located on the rear surface of the display module DM overlapping the second non-bending area NBA2 in a state in which the display panel DP is not bent. Thus, the first protective member PF1 and the second protective member PF2 may be spaced apart from each other.

The protective members PF1 and PF2 may include a base layer including a plastic film. The plastic film may include a thermoplastic resin. For example, the thermoplastic resin may include at least one selected from the group consisting of polyethylene terephthalate (PET), polyethylene (PE), polyvinylchloride (PVC), polypropylene (PP), polystyrene (PS), polyacrylonitrile (PAN), styrene-acrylonitrile copolymer (SAN), acrylonitrile-butadiene-styrene (ABS), polymethyl methacrylate (PMMA), and combinations thereof. The electronic device EA according to the present disclosure includes the protective members PF1 and PF2 arranged on the rear surface of the display panel DP, thus may have suitable heat resistance, suitable fatigue strength, and suitable electrical properties, and may be less affected by a temperature and humidity.

Materials constituting the protective members PF1 and PF2 are not limited to a resin, and may include an organic/inorganic composite material. The protective members PF1 and PF2 may include a porous organic layer, and an inorganic material that fills pores of the organic layer.

The functional layer MP may be located on the rear surface of the display panel DP. In more detail, the functional layer MP may be located between the first protective member PF1 and the second protective member PF2 when the display panel DP is bent. The functional layer MP may be provided in the form of a plate. The functional layer MP may include a plurality of layers. For example, the functional layer MP may include a light-shielding layer, a heat dissipation layer, a cushion layer, and a plurality of adhesive layers.

The light-shielding layer may serve to solve a problem that components arranged in the display module DM are reflected onto the window panel WP through the active areas AA. The light-shielding layer may include a binder, and a plurality of pigment particles dispersed therein. The pigment particles may include carbon black or the like. The electronic device EA according to one or more embodiments may include the light-shielding layer, and thus may have an effect of improving light-shielding properties.

The heat dissipation layer may effectively dissipate heat generated by the display module DM. The heat dissipation layer may include at least one of graphite, copper (Cu), or aluminum (Al), which have suitable heat dissipation properties, but the present disclosure is not limited thereto. The heat dissipation layer may improve heat dissipation properties, and may have electromagnetic wave shielding or electromagnetic wave absorbing properties.

The cushion layer may be a synthetic resin foam. The cushion layer may include a matrix and a plurality of pores. The cushion layer may have elasticity, and may have a porous structure.

The matrix may include a flexible material. The matrix includes a synthetic resin. For example, the matrix may include at least one of acrylonitrile butadiene styrene copolymer (ABS), polyurethane (PU), polyethylene (PE), ethylene vinyl acetate (EVA), or polyvinyl chloride (PVC).

The plurality of pores may suitably absorb an impact applied to the cushion layer. The plurality of pores may be defined as the cushion layer having a porous structure.

According to one or more embodiments, at least one of the light-shielding layer, the heat dissipation layer, or the cushion layer included in the functional layer MP may be omitted, and a plurality of layers may be provided as a single layer, but the present disclosure is not limited to one or more embodiments.

The electronic module EM includes the motherboard and various functional modules mounted on the motherboard to operate the electronic device EA. The motherboard may be electrically connected to the display module DM through the connector. Here, the motherboard may include a rigid type printed circuit board. The electronic module EM is electrically connected to the power supply module PSM. The electronic module EM and the power supply module PSM may be accommodated in the housing HU.

The power supply module PSM supplies power required for an overall operation of the electronic device EA. The power supply module PSM may include a general battery device.

As illustrated in FIG. 2B, the display module DM may include the display panel DP and the input sensor ISP. The input sensor ISP detects input of the user. The capacitive input sensor ISP may be located on the display panel DP.

The electronic module EM may include a control module 10, a wireless communication module 20, an image input module 30, an audio input module 40, an audio output module 50, a memory 60, and an external interface module 70. The electronic module EM may include the main circuit board, and the modules may be mounted on the main circuit board, or may be electrically connected to the main circuit board through the flexible circuit board. The input sensor ISP may be connected to the main circuit board through the connector or the like. The electronic module EM is electrically connected to the power supply module PSM.

The control module 10 controls an overall operation of the electronic device EA. For example, the control module 10 activates or deactivates the display module DM in accordance with the input of the user. The control module 10 may control the image input module 30, the audio input module 40, and the audio output module 50 in accordance with the input of the user. The control module 10 may include at least one microprocessor.

The wireless communication module 20 may transmit/receive a wireless signal to/from another terminal using a Bluetooth line or a Wi-Fi line. The wireless communication module 20 may transmit/receive a voice signal using a general communication line. The wireless communication module 20 may include a plurality of antenna modules.

The image input module 30 may process an image signal, and may convert the processed image signal into image data that may be displayed on the display module DM. The audio input module 40 may receive an external audio signal through a microphone in a recording mode, a voice recognition mode, and/or the like, and may convert the received external audio signal into electrical voice data. The audio output module 50 may convert audio data received from the wireless communication module 20, or audio data stored in the memory 60, into a sound, and may output the converted sound to the outside.

The external interface module 70 may serve as an interface connected to an external charger, a wired/wireless data port, a card socket (e.g., a memory card and a subscriber identification module (SIM)/user identification module (UIM) card), and the like.

The power supply module PSM may supply the power required for the overall operation of the electronic device EA. The power supply module PSM may include a general battery device.

An electro-optical module ELM may be an electronic component that outputs or receives an optical signal. The electro-optical module ELM may include a camera module and/or a proximity sensor. The camera module captures an external image through a sensing area DP-TA.

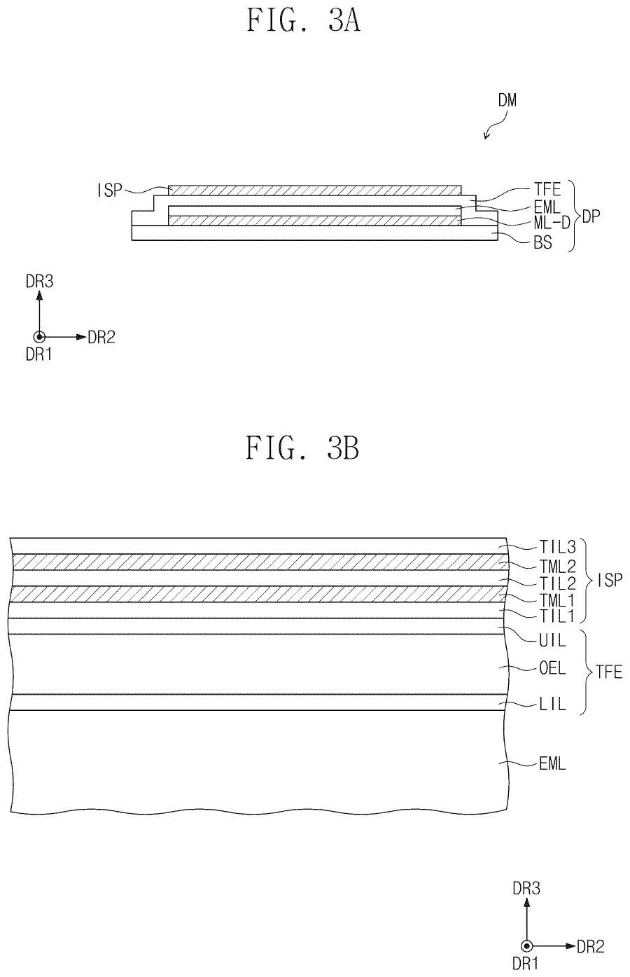

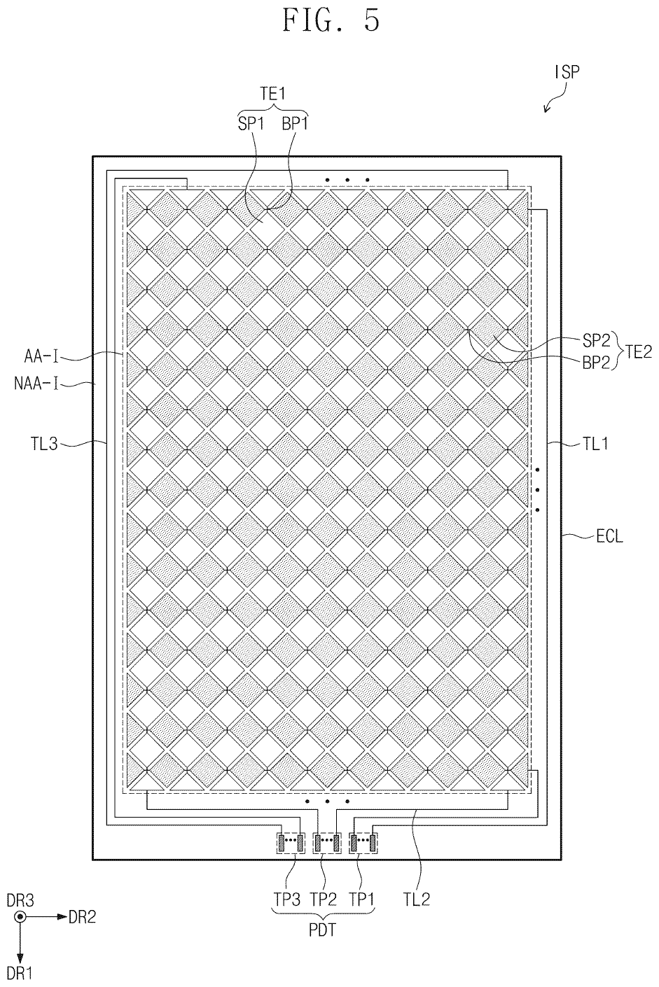

FIG. 3A is a cross-sectional view of a display module according to one or more embodiments of the present disclosure. FIG. 3B is an enlarged cross-sectional view of the display module of FIG. 3A. FIG. 4 is a plan view of a display panel according to one or more embodiments of the present disclosure. FIG. 5 is a plan view of an input sensor according to one or more embodiments of the present disclosure. Referring to FIGS. 3A and 3B, the display module DM may include the display panel DP and the input sensor ISP.

The display panel DP may include a base substrate BS, a circuit element layer ML-D, a display element layer EML, and a thin film encapsulation layer TFE. The input sensor ISP may include a plurality of sensing insulating layers TIL1, TIL2, and TIL3 and a plurality of conductive layers TML1 and TML2.

The base substrate BS may be a base layer on which the circuit element layer ML-D, the display element layer EML, the thin film encapsulation layer TFE, and the input sensor ISP may be laminated. The base substrate BS may be flexible or rigid, and may be provided as a single layer or may have a multi-layer structure, but the present disclosure is not limited thereto.

The circuit element layer ML-D may be located on the base substrate BS. The circuit element layer ML-D may include a plurality of insulating layers, a plurality of conductive layers, and a semiconductor layer. The plurality of conductive layers of the circuit element layer ML-D may constitute signal lines or a control circuit of the pixels PX (see FIG. 4).

The display element layer EML may be located on the circuit element layer ML-D. The display element layer EML may include organic light-emitting diodes. However, this is only an example, and the display element layer EML according to one or more embodiments of the present disclosure may include inorganic light-emitting diodes, organic-inorganic light-emitting diodes, or liquid crystal layers.

The thin film encapsulation layer TFE may include an organic layer OEL, and a plurality of inorganic layers LIL and UIL that seal the organic layer OEL. The thin film encapsulation layer TFE may seal the display element layer EML to block moisture and oxygen introduced into the display element layer EML.

The inorganic layers LIL and UIL may reduce or prevent external moisture or oxygen from penetrating into the display element layer EML. The inorganic layers LIL and UIL may include silicon nitride, silicon oxide, or a compound obtained by combining them. The inorganic layers LIL and UIL may be formed through a deposition process.

The organic layer OEL may be located on the display element layer EML to provide a flat surface. Curves, particles, or the like formed on an upper surface of the display element layer EML may be covered by the organic layer OEL, and thus may have little to no effect on components, for example, the input sensor ISP, formed on the organic layer OEL.

The input sensor ISP is located on the thin film encapsulation layer TFE. The input sensor ISP may be directly located on the thin film encapsulation layer TFE, and may be formed through a continuous process with the thin film encapsulation layer TFE. The input sensor ISP may detect an external input using either a self-capacitance manner or a mutual capacitance manner. Sensing patterns included in the input sensor ISP may be variously modified, arranged, and connected in accordance with the manners.

The input sensor ISP may include the sensing insulating layers TIL1, TIL2, and TIL3 and the one or more conductive layers TML1 and TML2. The sensing insulating layers TIL1, TIL2, and TIL3 may include either an inorganic material or an organic material.

The first sensing insulating layer TIL1 may be directly located on the second inorganic layer UIL of the thin film encapsulation layer TFE. The first conductive layer TML1 is located on the first sensing insulating layer TIL1. The second sensing insulating layer TIL2 may be located on the first sensing insulating layer TIL1, and may cover the first conductive layer TML1. The second conductive layer TML2 is located on the second sensing insulating layer TIL2. The third sensing insulating layer TIL3 may be located on the second sensing insulating layer TIL2, and may cover the second conductive layer TML2. However, the present disclosure is not limited thereto, the first sensing insulating layer TIL1 may be omitted, and the first conductive layer TML1 may be directly located on the second inorganic layer UIL, but the present disclosure is not limited to one or more embodiments.

The conductive layers TML1 and TML2 according to one or more embodiments may include either a single-layer metal or a single-layer transparent conductive material. For example, the metal may include molybdenum, silver, titanium, copper, aluminum, and alloys thereof.

The transparent conductive material may include transparent conductive oxides, such as indium tin oxide (ITO), indium zinc oxide (IZO), zinc oxide (ZnO), and indium tin zinc oxide (ITZO). In addition, the transparent conductive material may include a conductive polymer, such as poly(3,4-ethylenedioxythiophene) (PEDOT), metal nanowires, graphene, or the like.

Further, the conductive layers TML1 and TML2 may include metal layers having multi-layer structures. The multi-layer metal layers may have, for example, a three-layer structure of titanium/aluminum/titanium. The multi-layer conductive layers TML1 and TML2 may include at least one metal layer and at least one transparent conductive layer.

Referring to FIG. 4, the active area AA of the display panel DP may be an area on which an image is displayed, and the peripheral area NAA thereof may be an area on which a driving circuit, a driving wiring line, or the like are arranged. Light-emitting elements included in the plurality of pixels PX may be arranged in the active area AA. The active area AA may overlap at least a portion of the transmissive area TA (see FIG. 1), and the peripheral area NAA (see FIG. 1) may be covered by the bezel area BZA.

The display panel DP according to one or more embodiments may include the first non-bending area NBA1, the bending area BA, and the second non-bending area NBA2 that are arranged in the first direction DR1. The first non-bending area NBA1 may include both the active area AA, and the peripheral area NAA adjacent to the active area AA.

A plurality of signal lines GL, DL, PL, and EL may be connected to the pixels PX, and may transmit electrical signals to the pixels PX. Among the signal lines included in the display panel DP, the scan line GL, the data line DL, the power line PL, and the light-emitting control line EL are illustrated. However, this is only an example, and the signal lines GL, DL, PL, and EL according to one or more embodiments of the present disclosure may further include an initialization voltage line, but the present disclosure is not limited to one or more embodiments.

A power pattern VDD may be located in the peripheral area NAA. The power pattern VDD may be connected to a plurality of power lines PL. Accordingly, the display panel DP may include the power pattern VDD, and thus may provide the same power signal to the plurality of pixels PX.

Display pads PDD are arranged in the peripheral area NAA. The display pads PDD may include a first pad D1 and a second pad D2. A plurality of first pads D1 may be provided to be connected to the data lines DL, respectively. The second pad D2 may be connected to the power pattern VDD, and may be electrically connected to the power line PL. The display panel DP may be connected to the flexible circuit board FCB through the display pads PDD, and accordingly, may provide, to the pixels PX, electrical signals provided from the main circuit board MCB. Meanwhile, the display pads PDD may further include pads connected to the conductive layers TML1 and TML2 (see FIG. 3B) of the input sensor ISP, or may further include pads for receiving other electrical signals in addition to the first pad D1 and the second pad D2, but the present disclosure is not limited to one or more embodiments.

Referring to FIG. 5, the input sensor ISP may include a plurality of sensing electrodes TE1 and TE2, a plurality of sensing wiring lines TL1, TL2, and TL3, and a plurality of sensing pads PDT. The input sensor ISP may be divided into an active area AA-I, and a peripheral area NAA-I adjacent to the active area AA-I. The peripheral area NAA-I may surround the active area AA-I (e.g., in plan view). The active area AA-I may overlap at least a portion of the transmissive area TA (see FIG. 1), and the peripheral area NAA-I (see FIG. 1) may be covered by the bezel area BZA.

The plurality of sensing electrodes TE1 and TE2 may include the first sensing electrode TE1 and the second sensing electrode TE2.

The first sensing electrode TE1 may extend in the first direction DR1, may be provided in plurality, and may be arranged in the second direction DR2. The first sensing electrode TE1 may include first sensing patterns SP1 and first bridge patterns BP1. The first sensing patterns SP1 may be arranged in the first direction DR1. At least one first bridge pattern BP1 may be connected to two first sensing patterns SP1 adjacent to each other.

The second sensing electrode TE2 may extend in the second direction DR2, may be provided in plurality, and may be arranged in the first direction DR1. The second sensing electrode TE2 may include second sensing patterns SP2 and second bridge patterns BP2. The second sensing patterns SP2 may be arranged in the second direction DR2. At least one second bridge pattern BP2 may extend from two second sensing patterns SP2 adjacent to each other.

The sensing wiring lines TL1, TL2, and TL3 may be arranged in the peripheral area NAA-I. The sensing wiring lines TL1, TL2, and TL3 may include the first sensing wiring line TL1, the second sensing wiring line TL2, and the third sensing wiring lines TL3.

The first sensing wiring line TL1 may be connected to the second sensing electrode TE2. The second sensing wiring line TL2 may be connected to one end of the first sensing electrode TE1. The third sensing wiring line TL3 may be connected to the other end of the first sensing electrode TE1. The other end of the first sensing electrode TE1 may be opposite to the one end of the first sensing electrode TE1 in the first direction DR1.

The first sensing electrode TE1 according to one or more embodiments of the present disclosure may be connected to the second sensing wiring line TL2 and the third sensing wiring line TL3. Accordingly, sensitivity according to an area may be uniformly maintained with respect to the first sensing electrode TE1 having a relatively long length as compared to the second sensing electrodes TE2. However, this is only an example, and the third sensing wiring line TL3 according to one or more embodiments of the present disclosure may be omitted, but the present disclosure is not limited to one or more embodiments.

The sensing pads PDT may be arranged in the peripheral area NAA-I. The sensing pads PDT may include a first sensing pad TP1, a second sensing pad TP2, and a third sensing pad TP3. The first sensing pad TP1 may be connected to the first sensing wiring line TL1 and electrically connected to the first sensing electrode TE1. The second sensing pad TP2 may be connected to the second sensing wiring line TL2. The third sensing pad TP3 may be connected to the third sensing wiring line TL3. Thus, the second sensing pad TP2 and the third sensing pad TP3 may be electrically connected to the second sensing electrode TE2.

However, the present disclosure is not limited thereto, and the sensing pads PDT of the input sensor ISP may be arranged on the same layer as those of the display pads PDD of the display panel DP through contact holes defined in the sensing insulating layers TIL1, TIL2, and TIL3, but the present disclosure is not limited to one or more embodiments.

FIG. 6A is a cross-sectional view of the electronic device according to one or more embodiments of the present disclosure. FIG. 6B is a cross-sectional view of the electronic device according to one or more embodiments of the present disclosure.

FIG. 6A illustrates structures in a state in which the bending area BA of the display panel DP (see FIG. 4) of the display module DM is bent. The bending area BA may be bent with a curvature (e.g., predetermined curvature) along the virtual bending axis AX extending in the second direction DR2.

Referring to FIG. 6A, the electronic device EA according to one or more embodiments may include the window panel WP, the reflection-preventing panel RPP, the display module DM, the protective members PF1 and PF2, the functional layer MP, the cover member CM, and a protective layer RS. Further, the electronic device EA may include adhesive layers AM-W, AM-R, AM1, AM2, AM3, and AM4 arranged between adjacent components. Each of the adhesive layers AM-W, AM-R, AM1, AM2, AM3, and AM4 may include one of a pressure sensitive adhesive (PSA) film, an optically clear adhesive (OCA) film, or an optically clear resin (OCR).

The window panel WP may include a base part WB, a hard coating layer HC, and the bezel pattern BP. The base part WB may include an optically transparent insulating material. For example, the base part WB may include a glass substrate or a synthetic resin film. The hard coating layer HC for protecting the base part WB may be located on either a front surface or a rear surface of the base part WB. The hard coating layer HC may reduce or prevent damage to the base part WB due to scratches and the like. Further, a fingerprint-preventing layer may be further located in the base part WB.

The bezel pattern BP defines the bezel area BZA (see FIG. 1) of the window panel WP. The bezel pattern BP may be located at an edge of the rear surface of the base part WB.

The bezel pattern BP, which is a colored layer, may be formed through a coating manner. The bezel pattern BP may include a polymer resin and a pigment mixed with the polymer resin. For example, the polymer resin may be an acrylic resin or polyester, and the pigment may be a carbon-based pigment.

According to one or more embodiments, an edge of one of the front surface or the rear surface of the base part WB may have a chamfered shape. For example, an edge W-U of the front surface of the base part WB may have a rounded shape, and an edge W-B of the rear surface thereof may have an angular shape. The bezel pattern BP may overlap the edge W-B having a chamfered shape on the rear surface to cover the edge W-B.

The reflection-preventing panel RPP may be located under the window panel WP. The reflection-preventing panel RPP may reduce the reflectance of the external light beam input from the window panel WP. The window panel WP and the reflection-preventing panel RPP may be coupled by the adhesive layer AM-W therebetween.

The reflection-preventing panel RPP may be located on a front surface of the display module DM, which overlaps the first non-bending area NBA1. The reflection-preventing panel RPP and the display module DM may be coupled by the adhesive layer AM-R therebetween.

The cover member CM may be located on a front surface of the display module DM overlapping the bending area BA. The cover member CM may alleviate stresses generated when the portion of the display panel DP, which overlaps the bending area BA, is bent.

The first protective member PF1 may be located on a rear surface of the display module DM overlapping the first non-bending area NBA1. The display module DM and the first protective member PF1 may be coupled through the first adhesive layer AM1. According to one or more embodiments, a side surface P-E1 of the first protective member PF1 may be aligned with a side surface of the first adhesive layer AM1 in the third direction DR3.

The functional layer MP may be located under the first protective member PF1. The functional layer MP and the first protective member PF1 may be coupled through the second adhesive layer AM2. According to one or more embodiments, a side surface M-E of the functional layer MP may be aligned with a side surface of the second adhesive layer AM2 in the third direction DR3. The functional layer MP and the second adhesive layer AM2 may expose a portion of a rear surface P-B of the first protective member PF1 adjacent to a side surface M-E of the functional layer MP.

The third adhesive layer AM3 may be located between the functional layer MP and the second protective member PF2. A side surface of the third adhesive layer AM3 may be located inside the display module DM further than the side surface M-E of the functional layer MP and a side surface P-E2 of the second protective member PF2.

The second protective member PF2 may be located on the rear surface of the display module DM overlapping the second non-bending area NBA2. The display module DM and the second protective member PF2 may be coupled through the fourth adhesive layer AM4.

The electronic device EA according to one or more embodiments may include the protective layer RS. The protective layer RS may be located in an inner space defined by the rear surface of the display module DM overlapping the bending area BA when the display module DM is bent, the side surface P-E1 of the first protective member PF1, the side surface M-E of the functional layer MP, the second surface P-E2 of the second protective member PF2, and sides surfaces of the adhesive layers AM1, AM2, AM3, and AM4.

Thus, the protective layer RS according to one or more embodiments of the present disclosure may be in contact with the side surface P-E1 of the first protective member PF1, the side surface M-E of the functional layer MP, the side surface P-E2 of the second protective member PF2, and the side surfaces of the adhesive layers AM1, AM2, AM3, and AM4. Further, the protective layer RS may be in contact with the rear surface P-B of the first protective member PF1.

As the protective layer RS is located in the inner space described above, the protective layer RS may support the display module DM to maintain a shape of the bending area BA when the display module DM is bent. Further, the protective layer RS may reduce or prevent foreign substances or the like from being introduced into the electronic device EA through the bending area BA. The protective layer RS according to one or more embodiments may include a resin.

The present disclosure may reduce or prevent the likelihood of a problem in which a resin penetrates between the adhesive layers AM1, AM2, AM3, and AM4 when the bending area BA is bent, as areas to which the resin is applied are set in a process of forming the protective layer RS.

Referring to FIG. 6B, an electronic device EA-a according to one or more embodiments may include the window panel WP, the reflection-preventing panel RPP, the display module DM, the protective members PF1 and PF2, the functional layer MP, the cover member CM, and the protective layer RS. Further, the electronic device EA-a may include the adhesive layers AM-W, AM-R, AM1, AM2, AM3, and AM4 arranged between adjacent components.

The descriptions of the window panel WP, the reflection-preventing panel RPP, the display module DM, the protective members PF1 and PF2, the functional layer MP, the cover member CM, the protective layer RS, and the adhesive layers AM-W, AM-R, AM1, AM2, and AM4 included in the electronic device EA-a are the same as those of FIG. 6A, and a difference will be mainly described.

A third adhesive layer AM3-a may be located between the functional layer MP and the second protective member PF2. A side surface of the third adhesive layer AM3-a may be located inside the display module DM from the side surface M-E of the functional layer MP and the side surface P-E2 of the second protective member PF2.

The third adhesive layer AM3-a according to one or more embodiments may include first to third layers P1, P2, and P3 that are sequentially laminated in the third direction DR3. Each of the first layer P1 and the third layer P3 may include one of the PSA film, the OCA film, or the OCR.

The second layer P2 may include a metal. According to one or more embodiments, the second layer P2 may include a metal, and thus may function as a ground. The display module DM may be connected to the second layer P2. Through the second layer P2, static electricity introduced into the display module DM may be discharged to the outside, or a path through which the static electricity flows may be provided. Accordingly, the display module DM having improved reliability may be provided.

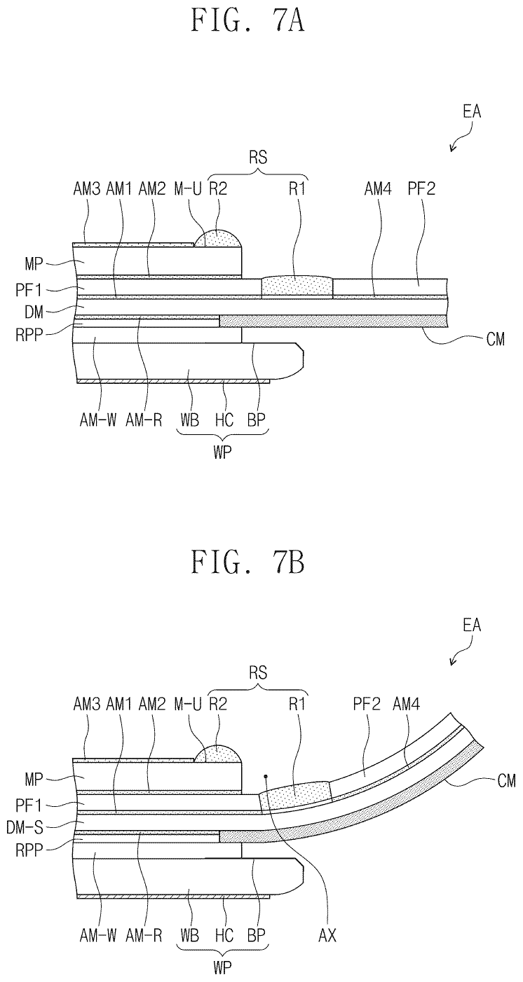

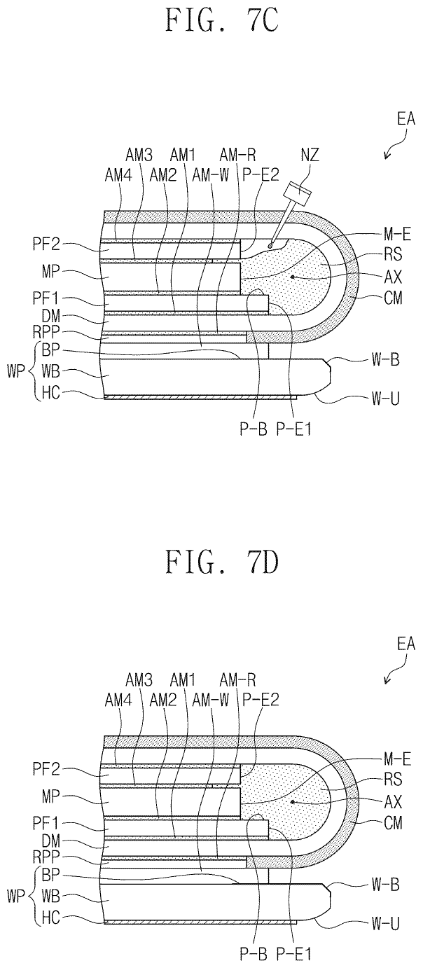

Hereinafter, a process of applying the protective layer RS will be described with reference to FIGS. 7A to 7D.

FIGS. 7A to 7D are cross-sectional views illustrating a method of manufacturing the electronic device according to one or more embodiments of the present disclosure. The same/similar reference numerals are used for the same/similar components described in FIGS. 1 to 6A, and a duplicated description thereof will be omitted.

Referring to FIG. 7A, a method of manufacturing an electronic device according to one or more embodiments may include an operation of providing a preliminary electronic device.

The preliminary electronic device may be provided in a state before the bending area BA (see FIG. 6A) of the display module DM is bent, that is, in a state in which the window panel WP, the reflection-preventing panel RPP, the display module DM, the first protective member PF1, the second protective member PF2, the functional layer MP, and the adhesive layers AM-W, AM-R, AM1, AM2, AM3, and AM4 are arranged.

Thereafter, the method may include an operation of applying a resin RS, which may be the same as or similar to the protective layer RS of FIG. 6A, to the preliminary electronic device. According to the present disclosure, in the operation of applying the resin RS, portions of the resin RS may be applied to different areas. For example, a first resin R1 may be applied to a first area. The “first area” may be defined as an area formed between the first protective member PF1 and the second protective member PF2 and the rear surface of the display module DM, which overlaps the bending area BA (see FIG. 6A), prior to the display module DM being bent.

A second resin R2 may be applied to a second area. The “second area” may be defined as an area adjacent to the bending area BA (see FIG. 6A) among an edge of the functional layer MP. The second area may be defined on a surface M-U exposed by the third adhesive layer AM3 among the functional layer MP.

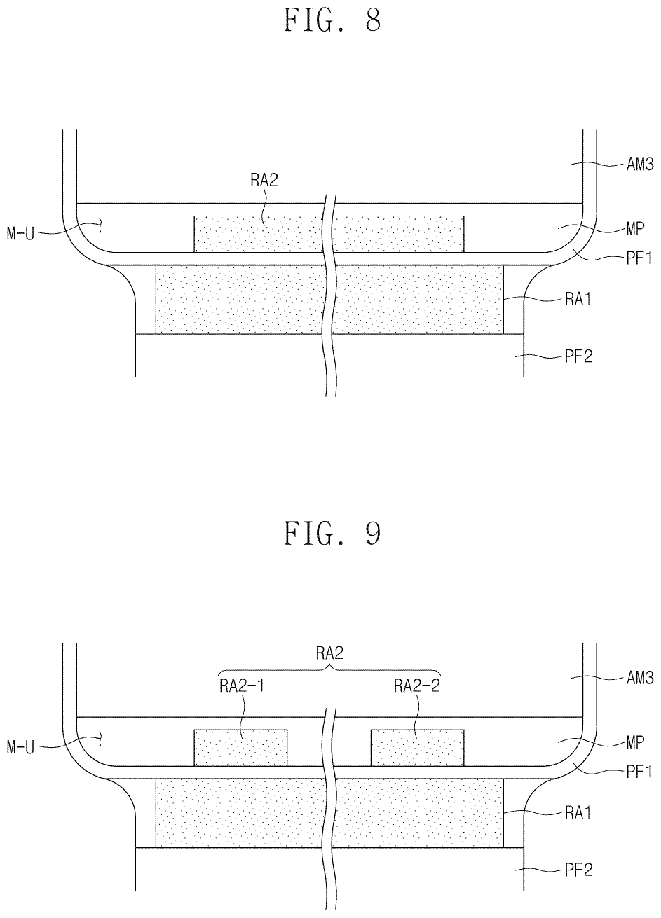

According to the present disclosure, the first area and the second area may be spaced apart from each other. Further, an area of the first area may be larger than an area of the second area. A plurality of second areas may be provided and may be spaced apart from each other. A description thereof will be made with reference to FIGS. 8 to 10.

Thereafter, referring to FIG. 7B, the method may include an operation of bending the display module DM. In the operation of bending the display module DM, the bending area BA (see FIG. 6A) may be bent along the bending axis AX extending in one direction. In this case, the first protective member PF1 and the second protective member PF2 may be bent to face each other.

The first resin R1 and the second resin R2 arranged in areas spaced apart from each other may be combined with each other when bent.

Thereafter, referring to FIG. 7C, the method may further include an operation of inserting an additional resin. In the operation of inserting the additional resin, after the display module DM is completely bent, when the resin RS is not sufficiently applied to the inner space defined by the rear surface of the display module DM overlapping the bending area BA, the side surface P-E1 of the first protective member PF1, the side surface M-E of the functional layer MP, the side surface P-E2 of the second protective member PF2, and the side surfaces of the adhesive layers AM1, AM2, AM3, and AM4, the resin RS may be additionally applied through an insertion device NZ. According to one or more embodiments, the operation of inserting the additional resin may be omitted.

Thereafter, referring to FIG. 7D, the inner space defined in a state in which the bending area BA of the display module DM is bent may be filled with the resin RS. In this case, the resin RS may be in contact with the side surface P-E1 of the first protective member PF1, the side surface M-E of the functional layer MP, the side surface P-E2 of the second protective member PF2, and the side surfaces of the adhesive layers AM1, AM2, AM3, and AM4.

According to the present disclosure, when the bending area BA (see FIG. 6A) of the display module DM is bent, the first resin R1 applied to the first area, and the second resin R2 is applied in the second area, the first and second areas being spaced apart from each other, and thus, penetration of the resin RS between the adhesive layers AM1, AM2, AM3, and AM4 may be reduced or prevented. Accordingly, by reducing waviness defects in the display module DM, the electronic device EA having improved display quality may be provided.

FIGS. 8 to 10 are embodiments related to the first area to which the first resin R1 is applied, and the second area to which the second resin R2 is applied, which have been described.

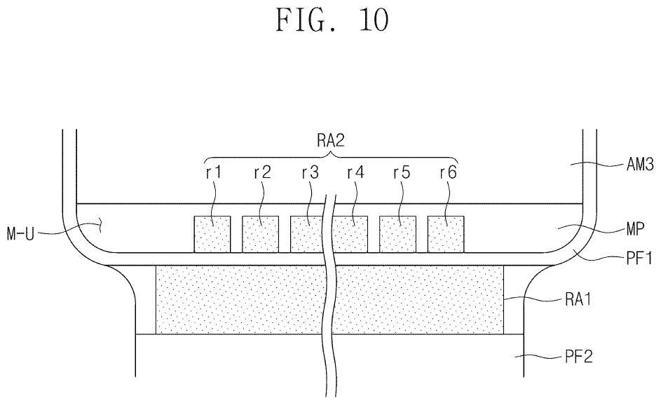

FIG. 8 is a rear view of the display panel according to one or more embodiments of the present disclosure. FIG. 9 is a rear view of the display panel according to one or more embodiments of the present disclosure. FIG. 10 is a rear view of the display panel according to one or more embodiments of the present disclosure.

Referring to FIG. 8, a first area RA1 may be defined as an area formed between the first protective member PF1 and the second protective member PF2. A second area RA2 may be defined on the surface M-U exposed by the third adhesive layer AM3 among the functional layer MP. According to one or more embodiments, the first area RA1 and the second area RA2 may extend in the same direction. The first area RA1 and the second area RA2 may be spaced apart from each other on a plane. An area of the first area RA1 may be larger than an area of the second area RA2.

Referring to FIG. 9, the first area RA1 may be defined as an area formed between the first protective member PF1 and the second protective member PF2. The second area RA2 may be defined on the surface M-U exposed by the third adhesive layer AM3 among the functional layer MP.

In one or more embodiments, the second area RA2 may include a (2-1)^{th} area RA2-1 and a (2-2)^{th} area RA2-2. The (2-1)^{th} area RA2-1 and the (2-2)^{th} area RA2-2 may be spaced apart from each other in a direction in which the first area RA1 extends. The first area RA1, the (2-1)^{th} area RA2-1, and the (2-2)^{th} area RA2-2 may be spaced apart from each other on a plane. An area of the first area RA1 may be larger than a sum of areas of the (2-1)^{th} area RA2-1 and the (2-2)^{th} area RA2-2.

Referring to FIG. 10, the first area RA1 may be defined as the area formed between the first protective member PF1 and the second protective member PF2. The second area RA2 may be defined on the surface M-U exposed by the third adhesive layer AM3 among the functional layer MP.

In one or more embodiments, the second area RA2 may include first to sixth sub-areas r1, r2, r3, r4, r5, and r6. The first to sixth sub-areas r1, r2, r3, r4, r5, and r6 may be arranged in the form of dots spaced apart from each other in the direction in which the first area RA1 extends.

The first area RA1 and the first to sixth sub-areas r1, r2, r3, r4, r5, and r6 may be spaced apart from each other on a plane. The area of the first area RA1 may be larger than a sum of areas of the first to sixth sub-areas r1, r2, r3, r4, r5, and r6. FIG. 10 illustrates the six sub-areas, but the present disclosure is not limited thereto, and the sub-areas may be added or omitted.

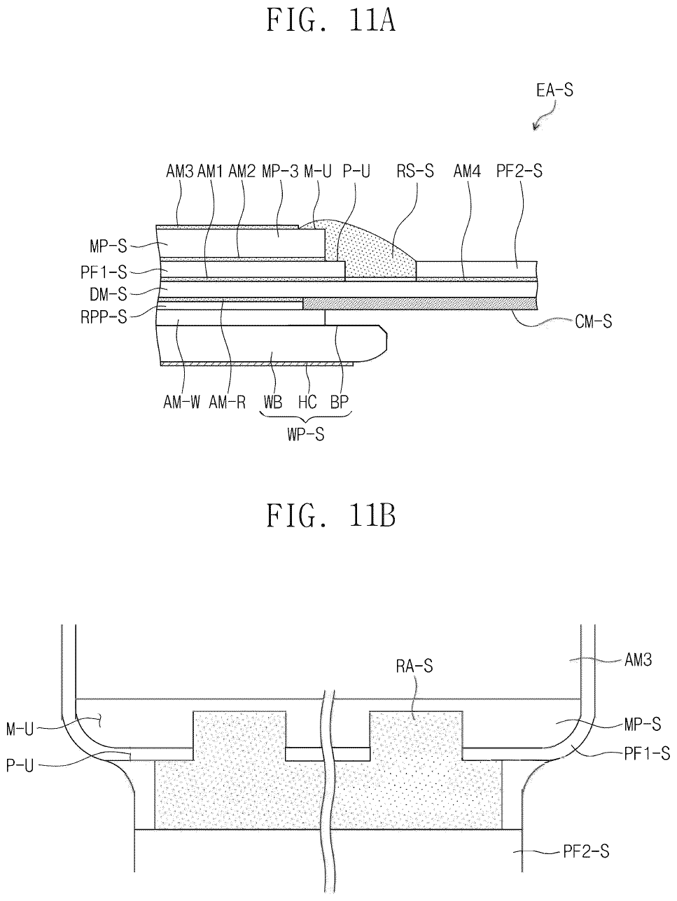

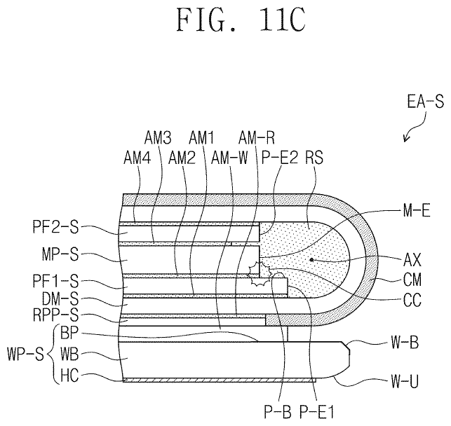

FIG. 11A is a cross-sectional view illustrating an electronic device according to a comparative example. FIG. 11B is a rear view of a display panel according to a comparative example. FIG. 11C is a cross-sectional view illustrating the electronic device according to a comparative example.

An electronic device EA-S according to one or more embodiments may have an area to which a resin RS-S is applied before a display module DM-S is bent, the area being different from that of the electronic device EA of one or more embodiments corresponding to FIG. 6A. According to one or more embodiments, before the display module DM-S is bent, an area RA-S to which the resin RS-S is applied may overlap an area between a first protective member PF1-S and a second protective member PF2-S, to overlap one surface P-U of the first protective member PF1-S exposed from a functional layer MP-S, and to overlap the surface M-U of the functional layer MP exposed from the third adhesive layer AM3. As in the present disclosure, when areas to which the resin RS (see FIG. 7B) is applied are connected to each other without being spaced apart from each other, and when the display module DM-S is bent, peeling defects CC in which the resin RS-S penetrates between the adhesive layers AM1, AM2, AM3, and AM4 may occur. When the resin RS-S penetrating between the adhesive layers AM1, AM2, AM3, and AM4 is visually recognized through a window panel WP-S, waviness defects in the display module DM-S may occur.

According to the present disclosure, when the bending area BA (see FIG. 6A) of the display module DM (see FIG. 7B) is bent, the first resin R1 (see FIG. 7B) applied to the first area RA1 (see FIG. 8) and the second resin R2 (see FIG. 7B) located in the second area RA2 (see FIG. 8), which are spaced apart from each other, may be combined, and thus, penetration of the resin RS (see FIG. 7C) between the adhesive layers AM1, AM2, AM3, and AM4 (see FIG. 7C) may be reduced or prevented. Accordingly, by reducing waviness defects in the display module DM, the electronic device EA (see FIG. 6A) having improved display quality may be provided.

According to one or more embodiments of the present disclosure, an electronic device in which, as resins applied to areas spaced apart from each other are combined with each other during bending, waviness defects in a display module are reduced, and thus display quality is improved may be provided.

Although the description has been made above with reference to one or more embodiments of the present disclosure, it may be understood that those skilled in the art or those having ordinary knowledge in the art may variously modify and changes the present disclosure without departing from the spirit and technical scope of the present disclosure described in the appended claims.

Thus, the technical scope of the present disclosure is not limited to the detailed description of the specification, but should be defined by the appended claims, with functional equivalents thereof to be included therein.

What is claimed is:

1. An electronic device comprising:
a display module comprising a bending area bent along a virtual bending axis, a first non-bending area and a second non-bending area spaced apart from each other with the bending area therebetween, a front surface, and a rear surface opposite to the front surface;
a first protective member below the rear surface and overlapping the first non-bending area;
a second protective member above the rear surface, overlapping the second non-bending area, and facing the first protective member;
a functional layer between the first protective member and the second protective member; and
a protective layer on the rear surface, overlapping the bending area, and contacting side surfaces of the first protective member, the functional layer, and the second protective member.

2. The electronic device of claim 1, wherein the side surface of the first protective member is closer to the bending area than the side surfaces of the functional layer and the second protective member.

3. The electronic device of claim 2, wherein the side surface of the functional layer exposes a portion of a rear surface of the first protective member that contacts the protective layer.

4. The electronic device of claim 1, further comprising a first adhesive layer between the first non-bending area and the first protective member, a second adhesive layer between the first protective member and the functional layer, a third adhesive layer between the functional layer and the second protective member, and a fourth adhesive layer between the second non-bending area and the second protective member.

5. The electronic device of claim 4, wherein the first to fourth adhesive layers comprise a pressure sensitive adhesive (PSA) film, an optically clear adhesive (OCA) film, or an optically clear resin (OCR).

6. The electronic device of claim 1, wherein the protective layer contacts side surfaces of the first to fourth adhesive layers.

7. The electronic device of claim 1, further comprising a window panel comprising a base part above the display module, a bezel pattern at at least a portion of an edge of a rear surface of the base part, and a hard coating layer above a front surface of the base part.

8. The electronic device of claim 7, wherein the rear surface of the base part or the front surface of the base part overlapping the bezel pattern has a chamfered shape.

9. The electronic device of claim 1, further comprising a driving element on the front surface overlapping the second non-bending area.

10. The electronic device of claim 9, further comprising a main circuit board on the front surface and overlapping the second non-bending area.

11. The electronic device of claim 1, further comprising a cover member above the front surface and overlapping the bending area.

12. The electronic device of claim 11, further comprising a reflection-preventing panel above the display module, and having a side surface contacting the cover member.

13. The electronic device of claim 1, wherein the display module comprises:
a display panel comprising a base layer, a transistor above the base layer, a light-emitting element connected to the transistor, and an encapsulation layer configured to cover the light-emitting element and comprising inorganic layers and an organic layer; and
an input sensor directly on the encapsulation layer and comprising conductive layers and at least one sensing insulating layer.

14. The electronic device of claim 1, wherein the protective layer comprises a resin.

15. A method of manufacturing an electronic device, the method comprising:
providing a preliminary electronic device comprising a display module comprising a first non-bending area, a bending area, and a second non-bending area, a first protective member on a rear surface of the display module and overlapping the first non-bending area, a second protective member on the rear surface of the display module and overlapping the second non-bending area, and a functional layer on the first protective member;
applying a resin to a first area overlapping the bending area and between the first protective member and the second protective member, and to a second area at an edge of the functional layer adjacent to the bending area and spaced apart from the first area; and
bending the bending area with respect to a bending axis extending in one direction such that the second protective member faces the functional layer.

16. The method of claim 15, wherein an area of the first area is larger than an area of the second area.

17. The method of claim 15, wherein the second area extends in the one direction.

18. The method of claim 15, wherein the second area comprises sub-units spaced apart from each other in the one direction.

19. The method of claim 15, further comprising combining the resin applied to the first area and the resin applied to the second area in a space defined between the first protective member, the functional layer, the second protective member, and the rear surface of the display module overlapping the bending area.

20. The method of claim 19, further comprising inserting an additional resin into the space after the bending of the bending area.
